(19) United States
(12) Patent Application Publication
(10) Pub. No.: US 2025/0160183 A1
(43) Pub. Date: May 15, 2025

(54) DISPLAY DEVICE AND OPTICAL ADHESIVE MATERIAL

(71) Applicant: Samsung Display Co., LTD., Yongin-si (KR)

(72) Inventors: Ki Cheol SONG, Yongin-si (KR); Yeon Joo SEO, Yongin-si (KR); Chang Woo LEE, Yongin-si (KR)

(73) Assignee: Samsung Display Co., LTD., Yongin-si (KR)

(21) Appl. No.: 18/829,433

(22) Filed: Sep. 10, 2024

(30) Foreign Application Priority Data
Nov. 9, 2023 (KR) 10-2023-0154743

(51) Int. Cl. H10K 59/80; C09J 7/38; C09J 11/06; C09J 11/08; G06F 3/044; H10K 59/40

(52) U.S. Cl. CPC H10K 59/879; C09J 7/385; C09J 11/06; C09J 11/08; G06F 3/0445; G06F 3/0446; H10K 59/40; C09J 2203/326; C09J 2301/302; C09J 2301/408; C09J 2301/414

(57) ABSTRACT

A display device includes a display layer including a light emitting element including a first electrode, a second electrode, and a light emitting layer electrically connected to the first electrode and the second electrode, and a sensor layer disposed on the display layer and including a conductive pattern layer, a passivation layer disposed on the conductive pattern layer and including an opening, and an optical adhesive layer disposed on the passivation layer, forming an interface with the passivation layer, and including an optical adhesive material. The passivation layer has a first refractive index. The optical adhesive layer has a second refractive index greater than the first refractive index. The optical adhesive material includes an aliphatic monomer, an aromatic monomer, an organic additive, and an inorganic particle.

### CROSS-REFERENCE TO RELATED APPLICATION(S)

This application claims priority to and benefits of Korean Patent Application No. 10-2023-0154743 under 35 U.S.C. § 119, filed on Nov. 9, 2023, in the Korean Intellectual Property Office (KIPO), the entire contents of which are incorporated herein by reference.

### BACKGROUND

### 1. Technical Field

The disclosure relates to a display device and an optical adhesive material.

### 2. Description of the Related Art

As information technology has developed, importance of a display device, which is a connection medium between a user and information, has been highlighted. Accordingly, the use of display devices such as a liquid crystal display device, an organic light emitting display device, and the like has been increasing.

The display device may include a display panel for displaying an image and a sensing panel for sensing an object. The sensing panel may be used to determine a position of a touch input provided by a user.

Light provided by the display panel may pass through the sensing panel and be provided to the outside. In order to improve the efficiency of the display device, the exit direction of light provided by the display panel needs to be closely defined. Accordingly, research and development is continuously being conducted to improve the light output efficiency of the display device.

### SUMMARY

An aspect of the disclosure is to provide a display device with improved light output efficiency and an optical adhesive material applicable to the display device.

Another aspect of the disclosure is to provide a display device that may have foldable characteristics while ensuring excellent optical characteristics, and an optical adhesive material applicable to the display device.

According to an embodiment of the disclosure, a display device may include a display layer including a light emitting element including a first electrode, a second electrode, and a light emitting layer electrically connected to the first electrode and the second electrode, and a sensor layer disposed on the display layer and including a conductive pattern layer, a passivation layer disposed on the conductive pattern layer and including an opening, and an optical adhesive layer disposed on the passivation layer, forming an interface with the passivation layer, and including an optical adhesive material. The passivation layer may have a first refractive index. The optical adhesive layer may have a second refractive index greater than the first refractive index. The optical adhesive material may include an aliphatic monomer, an aromatic monomer, an organic additive, and an inorganic particle.

The aliphatic monomer may be represented by one of Chemical Formula 1 to Chemical Formula 6.

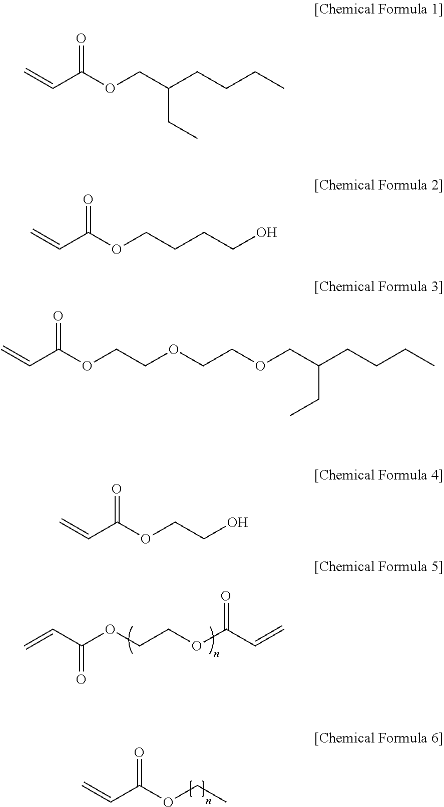

In Chemical Formula 5 and Chemical Formula 6, n may independently be an integer from 1 to 20.

The aliphatic monomer may constitute in a range of about 10 wt % to about 20 wt % of a total weight of the optical adhesive material.

The aromatic monomer may be represented by one of Chemical Formula 7 to Chemical Formula 12.

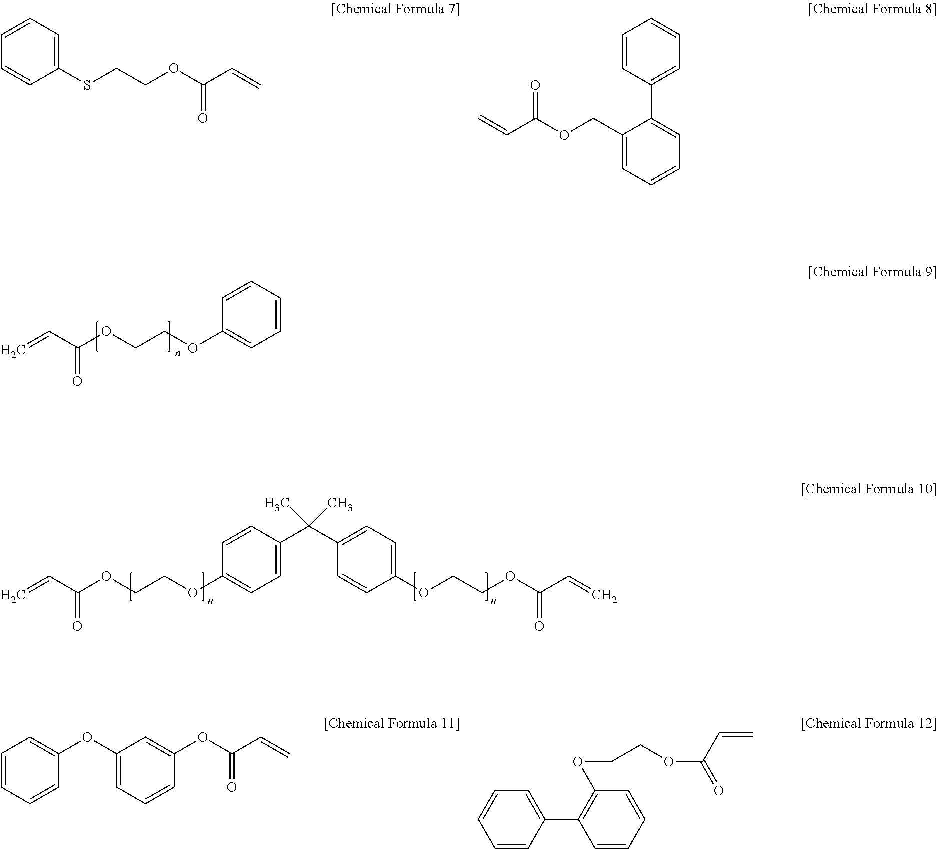

In Chemical Formula 9 and Chemical Formula 10, n may independently be an integer from 0 to 6.

The aromatic monomer may constitute in a range of about 40 wt % to about 65 wt % of a total weight of the optical adhesive material.

The organic additive may include a xylene resin. The xylene resin may constitute in a range of about 15 wt % to about 25 wt % of a total weight of the optical adhesive material.

The organic additive may include a sulfide-based aromatic organic material. The sulfide-based aromatic organic material may constitute in a range of about 10 wt % to about 20 wt % of a total weight of the optical adhesive material.

A refractive index of the optical adhesive layer may be in a range of about 1.56 to about 1.7.

A storage modulus of the optical adhesive material may be in a range of about 0.01 MPa to about 1.8 MPa at −20° C.

A ratio of a loss modulus to a storage modulus of the optical adhesive material may be in a range of about 3.0 to about 3.4.

A glass transition temperature of the optical adhesive material may be in a range of about −25° C. to about −20° C.

The passivation layer may include at least one of an acrylic resin, an epoxy resin, a phenol resin, a polyamide resin, a polyimide resin, a methacryl-based resin, a polyisoprene, a vinyl-based resin, a urethane-based resin, a cellulose-based resin, a siloxane-based resin, and perylene-based resin.

The first refractive index of the passivation layer may be in a range of about 1.45 to about 1.56.

The light emitting element may be an organic light emitting element.

The conductive pattern layer may include a first conductive pattern layer and a second conductive pattern layer. The sensor layer may further include an insulating layer disposed between the first conductive pattern layer and the second conductive pattern layer. The passivation layer and the second conductive pattern layer may be in contact with each other.

The optical adhesive layer may have a single-layered structure.

The display device may further include an upper layer disposed on the sensor layer directly adjacent to the optical adhesive layer.

The opening may overlap the light emitting layer in a plan view.

The display device may be a flexible display device.

According to an embodiment of the disclosure, an optical adhesive material may include an aliphatic monomer, an aromatic monomer, an organic additive including an organic material, and an inorganic material.

According to the embodiment of the disclosure, it may be possible to provide a display device with improved light output efficiency and an optical adhesive material applicable to the display device.

According to the embodiment of the disclosure, it is possible to provide a display device that may have foldable characteristics while ensuring excellent optical characteristics, and an optical adhesive material applicable to the display device.

### BRIEF DESCRIPTION OF THE DRAWINGS

FIG. 1 is a drawing for explaining a display device according to an embodiment.

FIG. 2 illustrates a schematic top plan view of a display device according to an embodiment.

FIG. 3 illustrates a schematic cross-sectional view of a stacked structure of a display device according to an embodiment.

FIG. 4 illustrates a schematic cross-sectional view of a display part according to an embodiment.

FIG. 5 illustrates a schematic cross-sectional view of a sensor part according to an embodiment.

FIG. 6 illustrates a schematic top plan view of sensing electrodes according to an embodiment.

FIG. 7 illustrates a schematic cross-sectional structure taken along line A-A′ in FIG. 6 and a schematic cross-sectional structure taken along line B-B′ in FIG. 6.

FIG. 8 illustrates a schematic cross-sectional view of a display device according to an embodiment.

### DETAILED DESCRIPTION OF THE EMBODIMENTS

Since the disclosure may be variously modified and have various forms, embodiments will be illustrated and described in detail in the following. This, however, by no means restricts the disclosure to the specific embodiments, and it is to be understood as embracing all included in the spirit and scope of the disclosure changes, equivalents, and substitutes.

Terms such as first, second, and the like will be used only to describe various constituent elements, and are not to be interpreted as limiting these constituent elements. These terms are only used to differentiate one constituent element from another. For example, a first constituent element may be referred to as a second constituent element, and similarly, a second constituent element may be referred to as a first constituent element, without departing from the scope of the disclosure. Singular forms are intended to include plural forms unless the context clearly indicates otherwise.

In the disclosure, it should be understood that the term “include”, “comprise”, “have”, or “configure” indicates that a feature, a number, a step, an operation, a constituent element, a part, or a combination thereof described in the specification is present, but does not exclude a possibility of presence or addition of one or more other features, numbers, steps, operations, constituent elements, parts, or combinations, in advance.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value.

In the specification and the claims, the phrase “at least one of” is intended to include the meaning of “at least one selected from the group of” for the purpose of its meaning and interpretation. For example, “at least one of A and B” may be understood to mean “A, B, or A and B.” In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

The disclosure relates to a display device and an optical adhesive material.

Hereinafter, a display device and an optical adhesive material according to an embodiment will be described with reference to the accompanying drawings.

### 1. Display Device

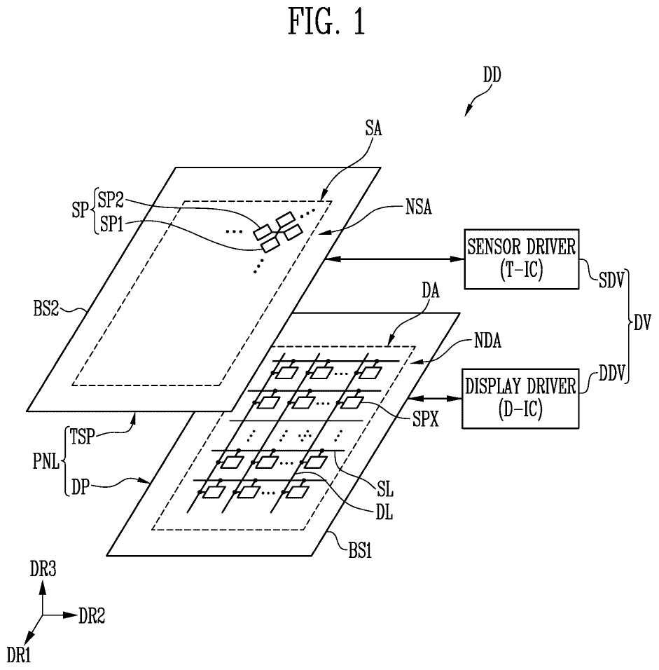

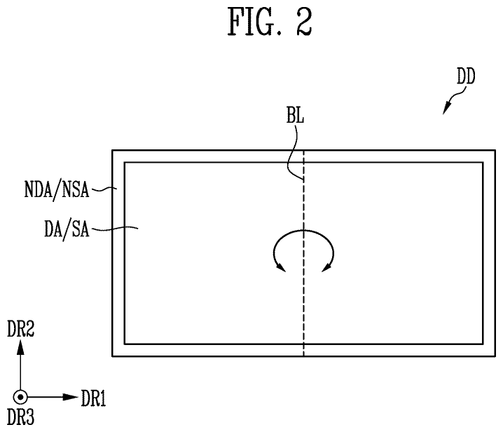

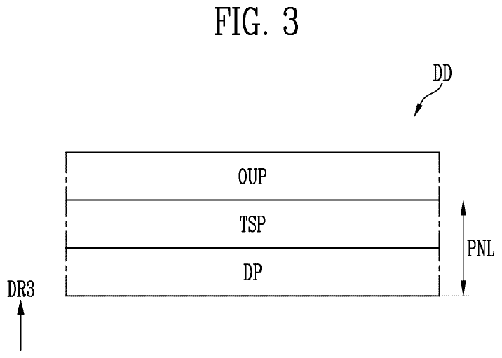

FIG. 1 is a drawing for explaining a display device according to an embodiment. FIG. 2 illustrates a schematic top plan view of a display device according to an embodiment. FIG. 3 illustrates a schematic cross-sectional view of a stacked structure of a display device according to an embodiment.

Referring to FIG. 1 to FIG. 3, a display device DD may be configured to provide (or emit) light.

In some embodiments, the display device DD may be applicable to various devices, and applicable devices are not limited to specific examples.

According to an embodiment, the display device DD may be a flexible display device. For example, the display device DD may be one or more of a rollable display device, a bendable display device, a curved display device, and a foldable display device. For example, the display device DD may be foldable along a bending line BL. In some embodiments, the bending line BL may extend in a second direction DR2. The number and position of bending lines BL are not particularly limited.

The display device DD may include a panel PNL and a driving circuit DV for driving the panel PNL. The display device DD may further include an outer part OUP.

The panel PNL may include a display part DP for displaying an image and a sensor part TSP capable of detecting a user input (for example, touch input).

The display part DP may be a display panel or display layer. The sensor part TSP may be a sensing panel, a sensor layer, or a sensing layer.

The panel PNL may include sub-pixels SPX and sensing electrodes SP. In some embodiments, the sub-pixels SPX may display an image in units of display frame periods. The sensing electrodes SP may sense a user input (for example, a touch input) in units of a sensing frame period. The sensing frame period and the display frame period may be independent of each other, or may be different from each other. The sensing frame period and the display frame period may be synchronized with each other or may be asynchronized.

The sensor part TSP including the sensing electrodes SP may obtain information about the user's touch input. According to an embodiment (for example, in a mutual capacitance method), the sensing electrodes SP may include a first sensing electrode SP1 that provides a first sensing signal and a second sensing electrode SP2 that provides a second sensing signal. In some embodiments, the first sensing electrode SP1 may be a transmitter (Tx) pattern electrode, and the second sensing electrode SP2 may be a receiver (Rx) pattern electrode. The information on the touch input (or touch event) may be information including a position of a touch that the user wants to provide.

However, the disclosure is not limited thereto. For example, according to an embodiment (for example, in a self-capacitance method), the sensing electrodes SP may be configured of one type of sensing electrodes without distinction between the first sensing electrode SP1 and the second sensing electrode SP2.

The driving circuit DV may include a display driver DDV for driving the display part DP and a sensor driver SDV for driving the sensor part TSP.

The display part DP may include a first base layer BS1 and sub-pixels SPX provided on the first base layer BS1. The sub-pixels SPX may be disposed in a display area DA. The first base layer BS1 may be a display base layer.

The first base layer BS1 (or display device DD) may include a display area DA in which an image is displayed and a non-display area NDA adjacent to the display area DA. In some embodiments, the display area DA may be disposed in the central area of the display part DP, and the non-display area NDA may be disposed adjacent to the periphery of the display area DA.

The first base layer BS1 may be a base substrate or a base member for supporting the display device DD. The first base layer BS1 may be a rigid substrate made of a glass material. In another embodiment, the first base layer BS1 may include a silicon wafer. In another embodiment, the first base layer BS1 may be a flexible substrate that is bendable, foldable, or rollable, and the base layer may include an insulating material such as a polymer resin including polyimide. However, the disclosure is not particularly limited thereto.

Scan lines SL and data lines DL, and sub-pixels SPX connected to the scan lines SL and the data lines DL may be disposed in the display area DA. The sub-pixels SPX may be selected by a scan signal of a turn-on level supplied from the scan lines SL to receive a data signal from the data lines DL and emit light with luminance corresponding to the data signal. Accordingly, an image corresponding to the data signal may be displayed in the display area DA. However, in the disclosure, the structure and driving method of the sub-pixels SPX are not particularly limited.

In the non-display area NDA, wires connected to the sub-pixels SPX of the display area DA and/or internal circuit portions may be disposed. For example, multiple wires for supplying various power and control signals to the display area DA may be disposed in the non-display area NDA.

The display part DP may output visual information (for example, an image). The type of the display part DP is not particularly limited. For example, the display part DP may be implemented as a self-luminous display panel, such as an organic light emitting display panel. In case that the display part DP implemented as a self-light emitting type, each pixel is not limited to an embodiment that only an organic light emitting element is included. For example, the light emitting element of each pixel may be formed as an organic light emitting diode, an inorganic light emitting diode, or a quantum dot/well light emitting diode. In some embodiments, the display part DP may be implemented as a non-light emitting type of display panel such as a liquid crystal display panel. In case that the display part DP is implemented as a non-light emitting type, the display device DD may additionally include a light source such as a light emitting device.

Hereinafter, for better understanding and ease of description, the display part DP will be described based on an embodiment that the display part DP is implemented as an organic light emitting display panel.

The sensor part TSP may include a second base layer BS2 and multiple sensing electrodes SP formed on the second base layer BS2. The sensing electrodes SP may be disposed in a sensing area SA on the second base layer BS2. The second base layer BS2 may be a sensor base layer.

The second base layer BS2 (or the display device DD) may include a sensing area SA capable of sensing a touch input or the like, and a non-sensing area NSA adjacent to the sensing area SA. In some embodiments, the sensing area SA may overlap at least an area of the display area DA in a plan view. For example, the sensing area SA may be set corresponding to the display area DA (for example, an area overlapping the display area DA), and the peripheral area NSA may be set corresponding to the non-display area NDA (for example, an area overlapping the non-display area NDA). In case that a touch input or the like is provided on the display area DA, it is possible to detect the touch input through the sensor part TSP.

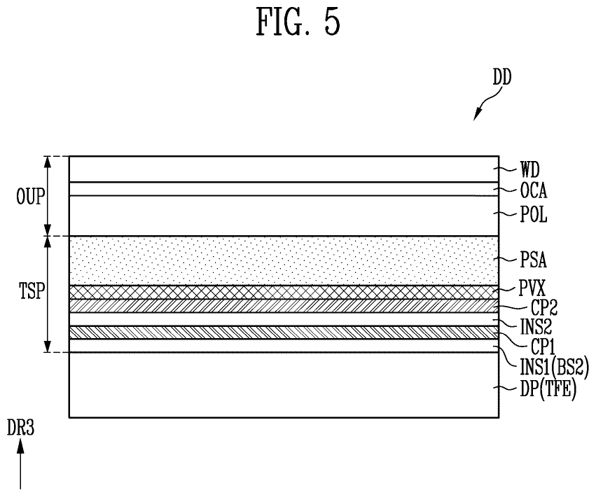

The second base layer BS2 may include one or more insulating layers (for example, a first insulating layer INS1 (see FIG. 5)). For example, the first insulating layer INS1 for forming the second base layer BS2 may be disposed on the display part DP to form a base for forming the sensing electrodes SP. However, the disclosure is not particularly limited thereto.

The sensing area SA may be set as an area capable of reacting to a touch input (for example, an active area of a sensor). To this end, the sensing electrodes SP for sensing the touch input or the like may be disposed in the sensing area SA.

The sensor part TSP may obtain information about an input provided from the user. The sensor part TSP may recognize a touch input. The sensor part TSP may recognize the touch input by using a capacitive sensing method. In another embodiment, the sensor part TSP may sense the touch input by using a mutual capacitance method, or may sense the touch input by using a self-capacitance method.

In some embodiments, each of the first sensing electrodes SP1 may extend in the first direction DR1. The first sensing electrodes SP1 may be arranged in the second direction DR2. The second direction DR2 may be different from the first direction DR1. For example, the second direction DR2 may be a direction orthogonal to the first direction DR1.

In some embodiments, each of the second sensing electrodes SP2 may extend in the second direction DR2. The second sensing electrodes SP2 may be arranged in the first direction DR1.

In some embodiments, the first sensing electrodes SP1 and the second sensing electrodes SP2 may have the same (for example, substantially the same) shape in a plan view. For example, the first sensing electrodes SP1 with the Tx pattern and the second sensing electrodes SP2 with the Rx pattern may have a corresponding shape (for example, substantially the same shape), and accordingly, the sensing performance of the touch event may be uniformly set in the sensing area SA.

Sensing lines for electrically connecting the sensing electrodes SP to the sensor driver SDV or the like may be disposed in the non-sensing area NSA of the sensor part TSP.

The driving circuit DV may include a display driver DDV for driving the display part DP and a sensor driver SDV for driving the sensor part TSP.

The display driver DDV may be configured to be electrically connected to the display part DP to drive the sub-pixels SPX. The sensor driver SDV may be configured to be electrically connected to the sensor part TSP to drive the sensor part TSP.

The outer part OUP may be substantially disposed on an outer side of the display device DD. The outer part OUP may be disposed on the sensor part TSP. Light provided from the display part DP may pass through the outer part OUP and be outputted to the outside. In some embodiments, the outer part OUP may include a window part WD (see FIG. 5). In some embodiments, the outer part OUP may further include a polarizing layer POL (see FIG. 5). However, the disclosure is not limited thereto. The outer part OUP may further include a color filter layer that selectively transmits light of one color.

The outer part OUP may be an outer light layer or upper layer.

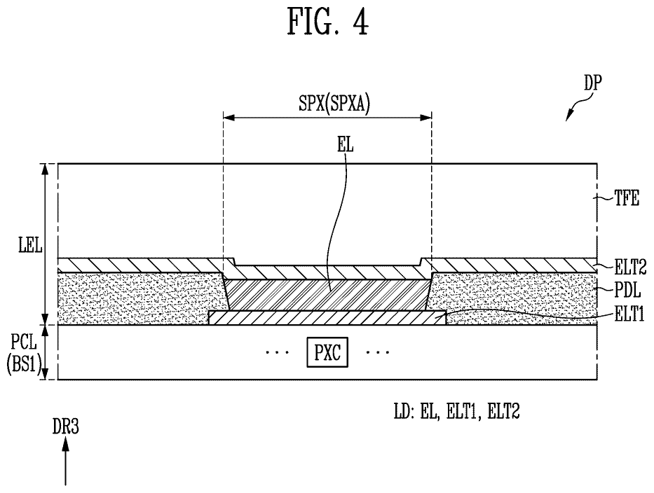

Hereinafter, referring to FIG. 4, an embodiment of the display part DP will be described. FIG. 4 illustrates a schematic cross-sectional view of a display part according to an embodiment.

Referring to FIG. 4, the display part DP may include a pixel circuit layer PCL and a light emitting element layer LEL.

The pixel circuit layer PCL may include a pixel circuit PXC for driving light emitting elements LD. The pixel circuit layer PCL may include a first base layer BS1, conductive layers for forming the pixel circuits PXC, and insulating layers disposed between the conductive layers.

The pixel circuit PXC may include circuit elements including a transistor. The pixel circuit PXC may include a driving transistor. The pixel circuit PXC may be electrically connected to the light emitting elements LD to provide electrical signals for the light emitting elements LD to emit light.

The light emitting element layer LEL may be disposed on the pixel circuit layer PCL. In some embodiments, the light-emitting-element layer LEL may include the light emitting element LD, a pixel defining film PDL, and an encapsulation film TFE.

The light emitting element LD may be disposed on the pixel circuit layer PCL. In some embodiments, the light emitting element LD may include a first electrode ELT1, a light emitting layer EL, and a second electrode ELT2. In some embodiments, the light emitting layer EL may be disposed in an area defined by the pixel defining film PDL. The pixel defining film PDL may be adjacent to the periphery of the light emitting layer EL. A surface of the light emitting layer EL may be electrically connected to the first electrode ELT1, and another surface of the light emitting layer EL may be electrically connected to the second electrode ELT2.

The first electrode ELT1 may be an anode electrode for the light emitting layer EL, and the second electrode ELT2 may be a common electrode (or cathode electrode) for the light emitting layer EL. In some embodiments, the first electrode ELT1 and the second electrode ELT2 may include a conductive material. For example, the first electrode ELT1 may include a conductive material with reflective properties, and the second electrode ELT2 may include a transparent conductive material. However, the disclosure is not limited thereto.

The light emitting layer EL may have a multi-layered thin film structure including a light generation layer. The light emitting layer EL may include a hole injection layer for injecting holes, a hole transport layer for increasing chance of recombination between holes and electrons by having excellent hole transport and blocking movement of electrons that are not be combined in a light generation layer, a light generation layer that emits light by recombination of injected electrons and holes, a hole blocking layer for blocking movement of holes that are not be combined in a light generation layer, an electron transport layer for smoothly transporting electrons to the light generation layer, and an electron injection layer for injecting electrons. The light emitting layer EL may emit light based on electrical signals provided from the first electrode ELT1 and the second electrode ELT2.

The light emitting layer EL may form a sub-pixel SPX. The light emitting layer EL may form a sub-pixel area SPXA from which light of a color is emitted. In a plan view, the area of the light emitting layer EL and the sub-pixel area SPXA may correspond to each other. For example, each light emitting layer EL may correspond to each sub-pixel area SPXA.

In some embodiments, the light emitting layer EL may emit light of a color. For example, the sub-pixel SPX may include a first sub-pixel that provides light of a first color (for example, red), a second sub-pixel that provides light of a second color (for example, green), and a third sub-pixel that provides light of a third color (for example, blue). The sub-pixel area SPXA may include a first sub-pixel area in which the first sub-pixel is formed and the first color is visually recognized, a second sub-pixel area in which the second sub-pixel is formed and the second color is visually recognized, and a third sub-pixel area in which the third sub-pixel is formed and the third color is visually recognized. In some embodiments, the light emitting layer EL may provide light of different colors in the first to third sub-pixels, respectively. For example, the light emitting layer EL may include a first light emitting layer included in the first sub-pixel to provide light of the first color, a second light emitting layer included in the second sub-pixel to provide light of the second color, and a third light emitting layer included in the third sub-pixel to provide light of the third color. However, the disclosure is not limited thereto. For example, the light emitting layers EL may emit light of the same color in each of the first to third sub-pixels, and the display device DD may further include a quantum-dot layer and/or a color filter layer, thereby implementing a full-color display structure.

The pixel defining film PDL may be disposed on the pixel circuit layer PCL and define a position at which the light emitting layer EL is disposed. In some embodiments, the pixel defining film PDL may include an inorganic material. However, the disclosure is not limited thereto. The pixel defining film PDL may include an organic material.

The encapsulation film TFE may be disposed on the light emitting element LD. The encapsulation film TFE may offset a level difference generated by the light emitting element LD and the pixel defining film PDL. The encapsulation film TFE may include multiple insulating films covering the light emitting element LD. In some embodiments, the encapsulation film TFE may have a structure in which an inorganic film and an organic film are alternately stacked each other. In some embodiments, the encapsulation film TFE may be a thin film encapsulation film.

Hereinafter, referring to FIG. 5 to FIG. 7, the sensor part TSP and the outer part OUP disposed on the display part DP will be described.

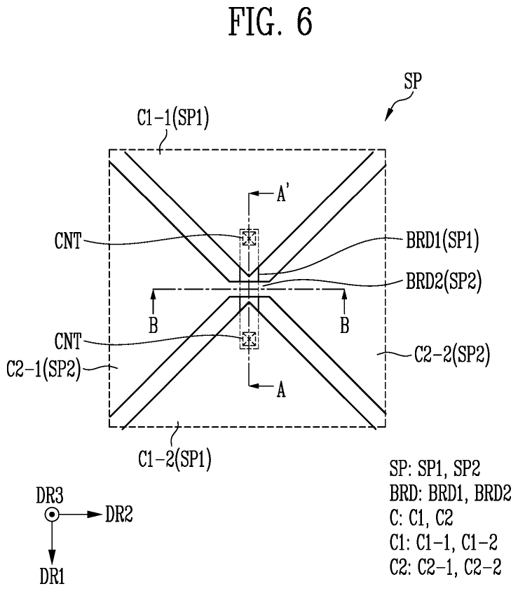

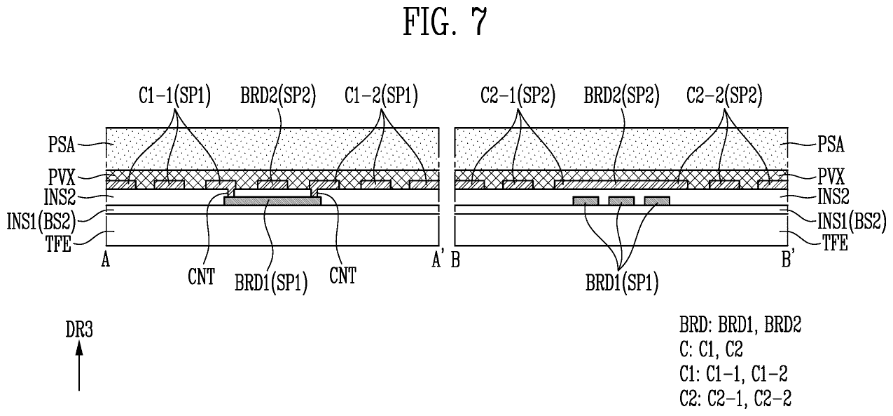

FIG. 5 illustrates a schematic cross-sectional view of a sensor part according to an embodiment. FIG. 6 illustrates a schematic top plan view of sensing electrodes according to an embodiment. FIG. 6 illustrates a schematic planar structure of areas in which a first sensing electrode SP1 and a second sensing electrode SP2 are adjacent to each other. FIG. 7 illustrates a schematic cross-sectional view of a sensor part and an outer part OUP according to an embodiment. FIG. 7 illustrates a schematic cross-sectional structure taken along line A-A′ in FIG. 6 and a schematic cross-sectional structure taken along line B-B′ in FIG. 6.

Referring to FIG. 5 to FIG. 7, the sensor part TSP may be disposed on the display part DP (for example, the encapsulation film TFE). The sensor part TSP may include a first insulating layer INS1, a first conductive pattern layer CP1, a second insulating layer INS2, a second conductive pattern layer CP2, a passivation layer PVX, and an optical adhesive layer PSA. In some embodiments, the optical adhesive layer PSA may include optical adhesive material, and may be referred to as “optical adhesive material PSA.”

In some embodiments, the first conductive pattern layer CP1 and the second conductive pattern layer CP2 may be patterned in an area to form the sensing electrodes SP. For example, a portion of the first conductive pattern layer CP1 may form the first sensing electrode SP1, and a portion of each of the first conductive pattern layer CP1 and the second conductive pattern layer CP2 may form the second sensing electrode SP2. In another embodiment, a portion of the second conductive pattern layer CP2 may form the first sensing electrode SP1, and a portion of each of the first conductive pattern layer CP1 and the second conductive pattern layer CP2 may form the second sensing electrode SP2. However, the disclosure is not limited thereto.

The first insulating layer INS1 may be disposed on the encapsulation film TFE. The first insulating layer INS1 may form the second base layer BS2 to provide an area in which the first conductive pattern layer CP1, the second insulating layer INS2, the second conductive pattern layer CP2, and the passivation layer PVX are disposed.

The first conductive pattern layer CP1 may be disposed on the first insulating layer INS1. The second conductive pattern layer CP2 may be disposed on the second insulating layer INS2. The first conductive pattern layer CP1 and the second conductive pattern layer CP2 may be spaced apart from each other, and the second insulating layer INS2 may be disposed between the first conductive pattern layer CP1 and the second conductive pattern layer CP2.

The first conductive pattern layer CP1 and the second conductive pattern layer CP2 may include a single-layered or multi-layered metal layer. For example, the first conductive pattern layer CP1 and the second conductive pattern layer CP2 may include at least one of gold (Au), silver (Ag), aluminum (Al), molybdenum (Mo), chromium (Cr), titanium (Ti), nickel (Ni), neodymium (Nd), copper (Cu), platinum (Pt), and an alloy thereof. In some embodiments, the first conductive pattern layer CP1 and the second conductive pattern layer CP2 may include at least one transparent conductive material of a silver nanowire (AgNW), an indium tin oxide (ITO), an indium zinc oxide (IZO), an indium gallium zinc oxide (IGZO), an antimony zinc oxide (AZO), an indium tin zinc oxide (ITZO), a zinc oxide (ZnO), a tin oxide (SnO2), a carbon nano tube, and a graphene.

The second insulating layer INS2 may be disposed on the first conductive pattern layer CP1. The second insulating layer INS2 may be interposed between the first conductive pattern layer CP1 and the second conductive pattern layer CP2. The passivation layer PVX may be disposed on the second conductive pattern layer CP2.

The first insulating layer INS1 may include at least one of an inorganic material and an organic material. The second insulating layer INS2 may include at least one of an inorganic material and an organic material. In some embodiments, the first insulating layer INS1 and the second insulating layer INS2 may include one or more of an inorganic material and an organic material. The inorganic material may include at least one of a silicon nitride (SiNₓ), a silicon oxide (SiOₓ), a silicon oxynitride (SiOₓN_{y}), and an aluminum oxide (AlOₓ). The organic material may include at least one of an acrylic resin, an epoxy resin, a phenol resin, a polyamide resin, and a polyimide resin. However, the disclosure is not limited thereto.

The sensing electrodes SP may include a cell C and a bridge BRD. The cell C may have a relatively large area, and the bridge BRD may have a relatively small area in a plan view. The cells C adjacent to each other may be electrically connected by the bridge BRD. The cell C may include a first cell C1 and a second cell C2. The bridge BRD may include a first bridge BRD1 and a second bridge BRD2.

In some embodiments, the first cell C1 and the second cell C2 may be formed by the second conductive pattern layer CP2. The first bridge BRD1 may be formed by the first conductive pattern layer CP1. A portion of the second bridge BRD2 may be formed by the first conductive pattern layer CP1, and another portion of the second bridge BRD2 may be formed by the second conductive pattern layer CP2.

However, the disclosure is not necessarily limited thereto. For example, the first cell C1 and the second cell C2 may be formed by the first conductive pattern layer CP1. The first bridge BRD1 may be formed by the second conductive pattern layer CP2. A portion of the second bridge BRD2 may be formed by the second conductive pattern layer CP2, and another portion of the second bridge BRD2 may be formed by the first conductive pattern layer CP1.

In some embodiments, the sensing electrodes SP may have a mesh structure. The cells C and the bridges BRD may have a mesh structure in a plan view. For example, the second conductive pattern layer CP2 for forming the sensing electrodes SP may be patterned according to the mesh structure. Because the sensing electrodes SP have a mesh structure, the capacitance that may form with other electrodes disposed at the lower portion of the cells C may be reduced.

The first sensing electrode SP1 may have a structure in which the first cells C1 having a relatively large area and the first bridge BRD1 having a relatively narrow area are connected. For example, the first cell C1 may include a (1-1)-th cell C1-1 and a (1-2)-th cell C1-2, and the first bridge BRD1 may electrically connect the (1-1)-th cell C1-1 and the (1-2)-th cell C1-2.

The second sensing electrode SP2 may have a structure in which the second cells C2 having a relatively large area and the second bridge BRD2 having a relatively narrow area are connected. For example, the second cell C2 may include a (2-1)-th cell C2-1 and a (2-2)-th cell C2-2, and the second bridge BRD2 may electrically connect the (2-1)-th cell C2-1 and the (2-2)-th cell C2-2.

In some embodiments, the first bridge BRD1 may be electrically connected to the (1-1)-th cell C1-1 through a contact portion CNT, and may be electrically connected to the (1-2)-th cell C1-2 through another contact portion CNT. Accordingly, the first bridge BRD1 disposed on a different layer from the first cell C1 may electrically connect the (1-1)-th cell C1-1 and the (1-2)-th cell C1-2 through the contact portion CNT. In some embodiments, the contact portion CNT may penetrate the second insulating layer INS2.

The first cell C1 and the second cell C2 may substantially have a diamond shape in a plan view. However, the shapes of the first cell C1 and the second cell C2 are not particularly limited thereto. For example, the first cell C1 and the second cell C2 may substantially have a quadrangular shape in a plan view.

The first sensing electrodes SP1 and the second sensing electrodes SP2 may be adjacent to each other with a virtual separation line between the first sensing electrodes SP1 and the second sensing electrodes SP2. The separation line SEL may be a virtual line disposed in the area between the first sensing electrodes SP1 and the second sensing electrodes SP2. For example, the separation line SEL may be disposed between the (1-1)-th cell C1-1 and the (1-2)-th cell C1-2. The separation line SEL may be disposed between the first bridge BRD1 and the (1-2)-th cell C1-2.

The optical adhesive layer PSA may be disposed on the passivation layer PVX. For example, the optical adhesive layer PSA may be disposed on (e.g., disposed directly on) the passivation layer PVX. The optical adhesive layer PSA may be disposed across the sub-pixel areas SPXA in a plan view.

The optical adhesive layer PSA may bond the outer part OUP to a component of the sensor part TSP. For example, respective layers of the display device DD may be sequentially disposed on the first base layer BS1, and the optical adhesive layer PSA may bond adjacent layers. The optical adhesive layer PSA may be adjacent to (e.g., directly adjacent to) the lowermost portion of the outer part OUP.

In some embodiments, the optical adhesive layer PSA may have a thickness greater than a thickness of the passivation layer PVX.

The optical adhesive layer PSA may transmit applied light. The optical adhesive layer PSA may define an optical path.

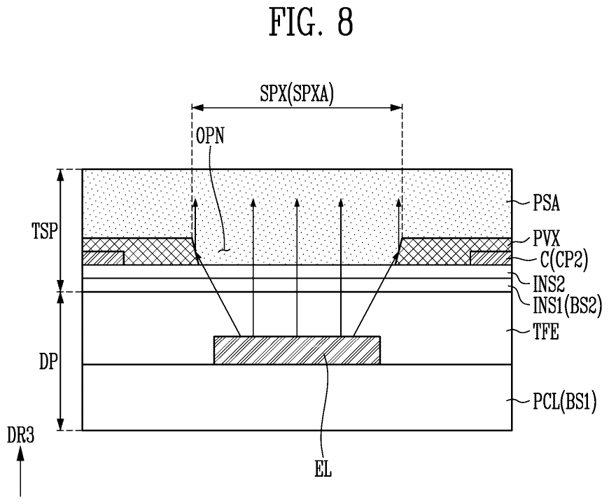

The optical adhesive layer PSA may form an interface with the passivation layer PVX. In some embodiments, light provided from the display part DP (for example, the light emitting element LD) may be refracted at the interface between the optical adhesive layer PSA and the passivation layer PVX, and the display device DD may provide light to the outside along an intended path. This will be described below with reference to FIG. 8.

The outer part OUP may be disposed on the sensor part TSP (for example, the optical adhesive layer PSA). For example, the outer part OUP may be disposed on (e.g., disposed directly on) the optical adhesive layer PSA.

In some embodiments, the outer part OUP may include a polarizing layer POL, a transparent adhesive layer OCA, and a window part WD.

The polarizing layer POL may be disposed on the optical adhesive layer PSA. The polarizing layer POL may be in contact with the optical adhesive layer PSA.

The polarizing layer POL may be configured to polarize applied light. In some embodiments, the polarizing layer POL may include a λ/4 retardation film. In some embodiments, the polarizing layer POL may include an absorption type polarizing layer or a reflection type polarizing layer (e.g., a wire grid polarizing layer). However, the disclosure is not limited thereto.

The transparent adhesive layer OCA may include an optically clear adhesive (OCA) material, but the disclosure is not limited thereto.

The transparent adhesive layer OCA may be disposed between the polarizing layer POL and the window part WD. The transparent adhesive layer OCA may couple the polarizing layer POL to the window part WD.

The window part WD may be disposed on the outside of the display device DD and may transmit light. The window part WD may protect other layers of the display device DD.

Hereinafter, the optical path defined in the display device DD according to an embodiment will be described with reference to FIG. 8. Descriptions that may be redundant to those described above are simplified or are not repeated.

FIG. 8 illustrates a schematic cross-sectional view of the display device according to an embodiment. FIG. 8 schematically illustrates an optical path of light provided by the light emitting layer EL. For example, an optical path of light provided by the light emitting layer EL according to an embodiment is represented by arrows.

FIG. 8 schematically illustrates a structure in which a portion of the second conductive pattern layer CP2 forms the cell C, and for better understanding and ease of description, an area in which the first conductive pattern layer CP 1 is not disposed is illustrated. For better understanding and ease of description, FIG. 8 schematically illustrates the display part DP. For example, FIG. 8 schematically illustrates the light emitting layer EL and the encapsulation layer TFE disposed on the pixel circuit layer PCL, and some components such as the first and second electrodes ELT1 and ELT2 are omitted. For better understanding and ease of description, FIG. 8 does not illustrate the outer part OUP. The applied light may pass through the outer part OUP and be emitted to the outside.

Referring to FIG. 8, the light provided by the light emitting layer EL may pass through the optical adhesive layer PSA and may be provided to the outside of the display device DD along an optical path.

The light emitting layer EL may be disposed in the sub-pixel area SPXA in a plan view. The light emitting layer EL may be disposed to correspond to an area in which the sub-pixel SPX is visually recognized in a plan view. The light emitting layer EL may not overlap the passivation layer PVX in a plan view. The light emitting layer EL may be disposed in an opening OPN in a plan view. The light emitting layer EL may overlap the opening OPN in a plan view.

The passivation layer PVX may be disposed in a partial area on the second insulating layer INS2. The passivation layer PVX may entirely cover the second conductive pattern layer CP2. The passivation layer PVX may surround an area and form the opening OPN in a plan view. The opening OPN may correspond to the sub-pixel SPX (for example, the sub-pixel area SPXA).

The passivation layer PVX may be in contact with the optical adhesive layer PSA. In some embodiments, the interface formed by the passivation layer PVX and the optical adhesive layer PSA may extend in a diagonal direction (for example, a different direction from the third direction DR3). As a portion of the passivation layer PVX, an end portion of the passivation layer PVX directly adjacent to the opening OPN may not overlap the light emitting layer EL in a plan view.

The passivation layer PVX may include an organic material. For example, the passivation layer PVX may include at least one of an acrylic resin, an epoxy resin, a phenol resin, a polyamide resin, a polyimide resin, a methacryl-based resin, a polyisoprene, a vinyl-based resin, a urethane-based resin, a cellulose-based resin, a siloxane-based resin, and perylene-based resin. However, the disclosure is not limited thereto.

The passivation layer PVX may have a refractive index (for example, first refractive index) less than a refractive index of the optical adhesive layer PSA. For example, the refractive index of the passivation layer PVX may be in a range of about 1.45 to about 1.56. In some embodiments, the passivation layer PVX may have a refractive index of about 1.54. However, the disclosure is not limited thereto.

The optical adhesive layer PSA may entirely cover the passivation layer PVX, and at least a portion of the optical adhesive layer PSA may be disposed in the opening OPN. The optical adhesive layer PSA may be an adhesive layer, or an optical layer that forms an interface with the passivation layer PVX to change the optical path.

The optical adhesive layer PSA may have a refractive index (for example, a second refractive index) greater than a refractive index of the passivation layer PVX. For example, the refractive index of the optical adhesive layer PSA may be in a range of about 1.56 to about 1.7. For example, the refractive index of the optical adhesive layer PSA may be in a range of about 1.56 to about 1.68. In some embodiments, the optical adhesive layer PSA may have a refractive index of about 1.58. In some embodiments, the optical adhesive layer PSA may have a refractive index of about 1.60. However, the disclosure is not limited thereto.

In some embodiments, some of the light provided by the light emitting layer EL may pass through the optical adhesive layer PSA without passing through the passivation layer PVX. For example, in a plan view, the light emitting layer EL may substantially overlap the opening OPN defined by an opening OPN of the passivation layer PVX, and the light emitted by the light emitting layer EL may pass through the optical adhesive layer PSA through the opening OPN and be visually recognized in front of the display device DD.

In some embodiments, some of the light provided by the light emitting layer EL may be totally reflected at the interface between the passivation layer PVX and the optical adhesive layer PSA and transmit through the optical adhesive layer PSA. For example, at least some of the light emitted by the light emitting layer EL, which is substantially directed in a diagonal direction (for example, a different direction from the third direction DR3), may be provided to the interface between the passivation layer PVX and the optical adhesive layer PSA. Due to the difference in refractive index between the passivation layer PVX and the optical adhesive layer PSA, the provided light may be totally reflected and guided in the display direction (for example, the third direction DR3) of the display device DD. Accordingly, the light emitting efficiency of the light emitting element LD may be improved, and the power required to implement an image having the same luminance may be reduced. According to the embodiment, the display device DD with improved light output efficiency may be provided.

In some embodiments, the optical adhesive layer PSA may be configured as a single layer. For example, the optical adhesive layer PSA may not include separate layers, but may include a structure in which materials are substantially uniformly distributed. Accordingly, the process step may be simplified, and the process cost may be reduced.

In some embodiments, the optical adhesive layer PSA may include a first base resin (for example, a first monomer), a second base resin (for example, a second monomer) different from the first base resin, an organic additive, and inorganic particles.

The first base resin may include an aliphatic monomer. The first base resin may include an aliphatic acrylate (for example, aliphatic meta acrylate) containing an aliphatic substituent. The type of the first base resin is not particularly limited, but in some embodiments, the first base resin may include an aliphatic acrylate containing an alkyl group having 1 to 30 carbon atoms. In an embodiment, the first base resin may include an aliphatic acrylate containing an alkyl group having 1 to 20 carbon atoms. In an embodiment, the first base resin may include an aliphatic acrylate containing an alkyl group having 1 to 10 carbon atoms.

In the specification, the alkyl group may be straight chain, branched chain, or cyclic. The carbon number of the alkyl group may be 1 to 50, 1 to 30, 1 to 20, 1 to 10, or 1 to 6. Examples of the alkyl group may include methyl group, ethyl group, n-propyl group, isopropyl group, n-butyl group, s-butyl group, t-butyl group, i-butyl group, 2-ethylbutyl group, 3, 3-dimethylbutyl group, n-pentyl group, i-pentyl group, neopentyl group, t-pentyl group, cyclopentyl group, 1-methylpentyl group, 3-methylpentyl group, 2-ethylpentyl group, 4-methyl-2-pentyl group, n-hexyl group, 1-methylhexyl group, 2-ethylhexyl group, 2-butylhexyl group, cyclohexyl group, 4-methylcyclohexyl group, 4-t-butylcyclohexyl group, n-heptyl group, 1-methylheptyl group, 2,2-dimethylheptyl group, 2-ethylheptyl group, 2-butylheptyl group, n-octyl group, t-octyl group, 2-ethyl octyl group, 2-butyloctyl group, 2-hexyl octyl group, 3,7-dimethyloctyl group, cyclooctyl group, n-nonyl group, n-decyl group, adamantyl group, 2-ethyldecyl group, 2-butyldecyl group, 2-hexyldecyl group, 2-octyldecyl group, n-undecyl group, n-dodecyl group, 2-ethyldodecyl group, 2-butyldodecyl group, 2-hexyldodecyl group, 2-octyldodecyl group, n-tridecyl group, n-tetradecyl group, n-pentadecyl group, n-hexadecyl group, 2-ethylhexadecyl group, 2-butylhexadecyl group, 2-hexylhexadecyl group, 2-octylhexadecyl group, n-heptadecyl group, n-octadecyl group, n-nonadecyl group, n-icosyl group, 2-ethylicosyl group, 2-butylicosyl group, 2-hexylicosyl group, 2-octylicosyl group, n-hen Icosyl group, n-docosyl group, n-tricosyl group, n-tetracosyl group, n-pentacosyl group, n-hexacosyl group, n-heptacosyl group, n-octacosyl group, n-nonacosyl group, and n-triacontyl group, but the disclosure is not limited thereto.

The first base resin may include a resin formed from an aliphatic monomer (or oligomer). For example, the first base resin may include an aliphatic acrylate. Entanglement between chains forming the first base resin may be increased and the modulus value of the optical adhesive layer PSA may be decreased, so the flexibility of the display device DD may be improved. Accordingly, the display device DD may be suitably prepared as a flexible device.

The first base resin may be included in an amount of less than or equal to about 30 wt % based on the total weight of the optical adhesive layer PSA. For example, the first base resin may be included in a range of about 10 wt % to about 30 wt % based on the total weight of the optical adhesive layer PSA. For example, the first base resin may be included in a range of about 10 wt % to about 20 wt % based on the total weight of the optical adhesive layer PSA.

In the specification, the physical quantities (for example, weight ratio, elastic modulus, and the like) of the compound included in the optical adhesive layer PSA may be defined based on the physical quantities of the target optical adhesive layer or target optical adhesive material.

According to an embodiment, the first base resin may be represented by one of Chemical Formula 1 to Chemical Formula 6.

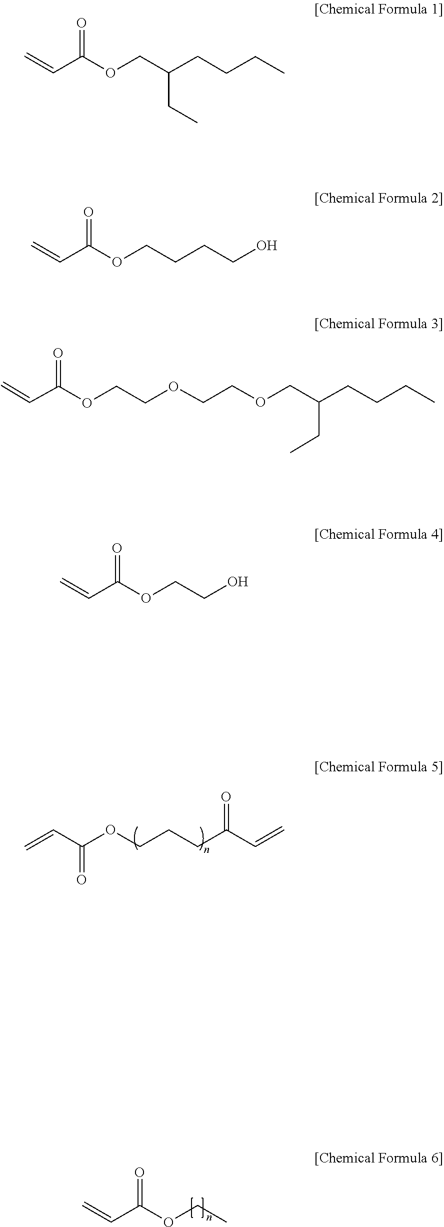

In Chemical Formula 5 and Chemical Formula 6, n may independently be an integer from 1 to 20.

In some embodiments, the glass transition temperature (Tg) of the first base resin may be less than or equal to about −10° C. For example, the glass transition temperature of the first base resin may be less than or equal to about −20° C. In case that the glass transition temperature of the first base resin satisfies the above-mentioned numerical range, excellent flexibility and processability may be realized, and durability of the display device DD may be improved.

The second base resin may include an aromatic monomer. The second base resin may include an aromatic acrylate (for example, aromatic meta acrylate) containing an aromatic substituent. The type of the second base resin is not particularly limited, but in some embodiments, the second base resin may include an aromatic acrylate containing an aryl group having 6 to 30 ring-forming carbon atoms. In an embodiment, the second base resin may include an aromatic acrylate containing an aryl group having 6 to 20 ring-forming carbon atoms. In an embodiment, the second base resin may include an aromatic acrylate containing an aryl group having 6 to 10 ring-forming carbon atoms.

In this specification, the aryl group may be a functional group or substituent derived from an aromatic hydrocarbon ring. The aryl group may be a monocyclic aryl group or a polycyclic aryl group. The number of ring-forming carbons of the aryl group may be in a range of about 6 to about 30. For example, the number of ring-forming carbons of the aryl group may be in a range of about 6 to about 20. For example, the number of ring-forming carbons of the aryl group may be in a range of about 6 to about 15. Examples of the aryl group may include phenyl group, naphthyl group, fluorenyl group, anthracenyl group, phenanthryl group, biphenyl group, terphenyl group, quaterphenyl group, quinquephenyl group, sexiphenyl group, triphenyl group, pyrenyl group, benzo fluoranthenyl group, chrysenyl group, and the like, but the disclosure is not limited thereto.

The second base resin may include a resin formed from an aromatic monomer (or oligomer). For example, the second base resin may include an aromatic acrylate. The second base resin may include an aromatic substituent having a high molar refractive index, and accordingly, the optical adhesive layer PSA may have a relatively high refractive index (for example, in a range of about 1.56 to about 1.7).

The second base resin may be included in an amount of less than or equal to about 65 wt % based on the total weight of the optical adhesive layer PSA. For example, the second base resin may be included in a range of about 40 wt % to about 65 wt % based on the total weight of the optical adhesive layer PSA.

According to an embodiment, the second base resin may be represented by one of Chemical Formula 7 to Chemical Formula 12.

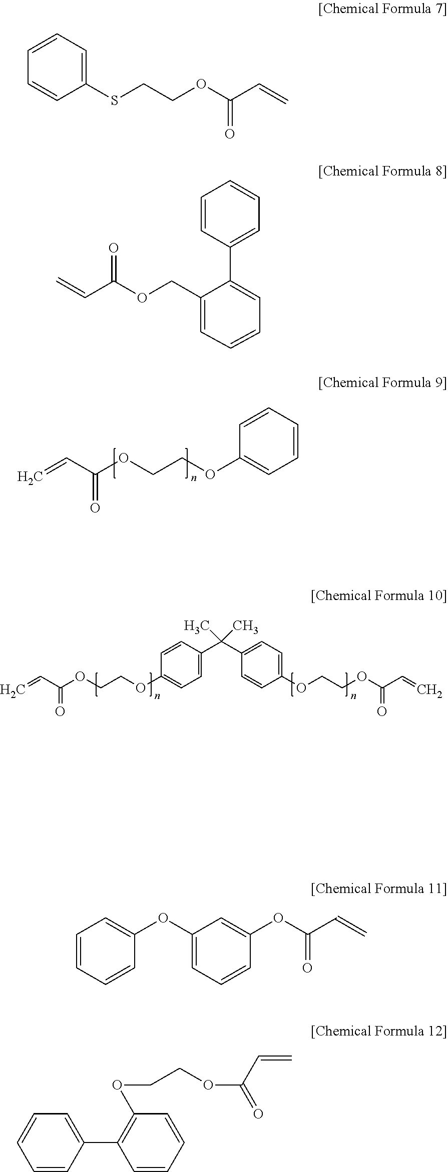

In Chemical Formula 9 and Chemical Formula 10, n may each independently be an integer from 0 to 6.

According to the embodiment, since the optical adhesive layer PSA includes both the first base resin and the second base resin, the display device DD may satisfy foldable characteristics and have excellent optical characteristics. The foldable characteristic may be a characteristic that is less likely to cause physical defects such as cracks even in case that bending or folding stress is applied to the display device DD.

The organic additive may be a plasticizer. In some embodiments, the organic additive may include a xylene resin and/or a sulfide-based aromatic organic material.

The xylene resin may improve the adhesion of the optical adhesive layer PSA and may serve as a plasticizer. The sulfide-based aromatic organic material may significantly improve plasticity even in case that the optical adhesive layer PSA has high refractive index characteristics.

The xylene resin may be included in a range of about 15 wt % to about 25 wt % based on the total weight of the optical adhesive layer PSA.

According to an embodiment, the xylene resin may be represented by Chemical Formula 13 below.

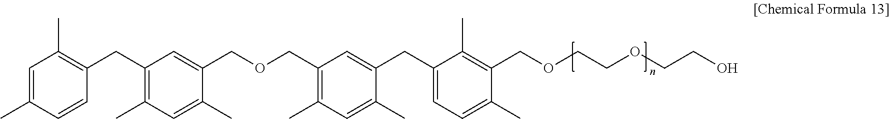

In Chemical Formula 13, n may be an integer from 0 to 100.

The sulfide-based aromatic organic material may be included in a range of about 10 wt % to about 20 wt % based on the total weight of the optical adhesive layer PSA.

According to an embodiment, the sulfide-based aromatic organic material may be represented by one of Chemical Formula 14 and Chemical Formula 15.

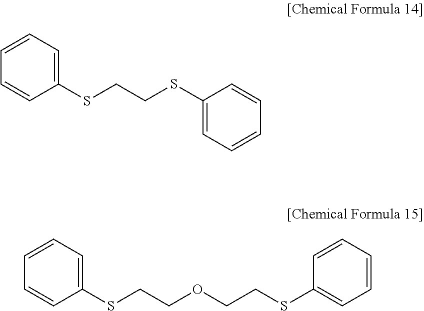 [SMILES: c1ccc(SCCSc2ccccc2)cc1 ; c1ccc(SCCOCCSc2ccccc2)cc1]

The inorganic particles may include a metal oxide. For example, the metal oxide may be an oxide of at least one of titanium (Ti), zirconium (Zr), aluminum (Al), indium (In), zinc (Zn), tin (Sn), and antimony (Sb). For example, the inorganic particles may include at least one of a zirconium oxide (ZrOₓ: for example, ZrO₂) and a titanium oxide (TiOₓ: for example, TiO₂).

The inorganic particles may be included in an amount of less than or equal to about 2 wt % based on the total weight of the optical adhesive layer PSA. For example, the inorganic particles may be included in a range of about 1.0 wt % to about 2.0 wt % based on the total weight of the optical adhesive layer PSA. For example, the inorganic particles may be included in a range of about 1.3 wt % to about 1.9 wt % based on the total weight of the optical adhesive layer PSA. For example, the inorganic particles may be included in a range of about 1.32 wt % to about 1.84 wt % based on the total weight of the optical adhesive layer PSA.

According to an embodiment, the content of the inorganic particles may be analyzed by a thermogravimetric analyzer (TGA) or wavelength-dispersive X-ray fluorescence (WDXRF) spectroscopy.

In some embodiments, the optical adhesive layer PSA may further include an inorganic particle, so that the refractive index numerical range of the optical adhesive layer PSA may be controlled. For example, the optical adhesive layer PSA may include the first base resin to improve the flexibility of the display device DD, and the first base resin may include an aliphatic monomer to allow the optical adhesive layer PSA to have relatively low refractive index characteristics. However, in some embodiments, the optical adhesive layer PSA may further include an inorganic particle, so that the optical adhesive layer PSA may have flexible properties and at the same time have a relatively high refractive index.

A storage modulus (G′) of the optical adhesive layer PSA at −20° C. may be in a range of about 0.01 MPa to about 2.4 MPa. For example, the storage modulus (G′) of the optical adhesive layer PSA at −20° C. may be in a range of about 0.01 MPa to about 1.8 MPa. For example, the storage modulus (G′) of the optical adhesive layer PSA at −20° C. may be about 1.6 MPa. In some embodiments, the storage modulus (G′) of the optical adhesive layer PSA at −20° C. may be about 0.1 MPa.

A loss modulus (G″) of the optical adhesive layer PSA at −20° C. may be in aa range of about 5.0 MPa to about 6.0 MPa or less. For example, the loss modulus (G″) of the optical adhesive layer PSA at −20° C. may be in a range of about 5.2 MPa to about 5.6 MPa. For example, the loss modulus (G″) of the optical adhesive layer PSA at −20° C. may be about 5.4 MPa.

A tan δ (G″/G′) of the optical adhesive layer PSA at −20° C. may be in a range of about 3.0 to about 3.4. The tan δ (G″/G′) of the optical adhesive layer PSA at −20° C. may be in a range of about 3.1 to about 3.3. For example, the tan δ (G″/G′) of the optical adhesive layer PSA at −20° C. may be about 3.25.

In case that the above-mentioned numerical range is satisfied, the optical adhesive layer PSA according to the embodiment may have excellent low-temperature characteristics. For example, in case that the optical adhesive layer PSA is subjected to a low temperature operating life (LTOL) test in a −20° C. environment, the buckling phenomenon may not occur.

Experimentally, as the storage modulus G′ of the optical adhesive layer PSA increases, the optical adhesive layer PSA may have a higher refractive index, but in case that the storage modulus is excessively increased, cracks may occur in the optical adhesive layer PSA in case that stress is applied to the optical adhesive layer PSA. According to an embodiment, the optical adhesive layer PSA may include the materials described above so as to have sufficient foldable characteristics while having a relatively high refractive index, and thus the above-mentioned risk may not occur.

In case that the storage modulus G′ of the optical adhesive layer PSA is excessively low, it may be difficult for the optical adhesive layer PSA to have sufficient adhesive performance, but in case that the storage modulus of the optical adhesive layer PSA satisfies the above-mentioned numerical range, the optical adhesive layer PSA may have sufficient adhesive performance.

The glass transition temperature of the optical adhesive layer PSA may be less than or equal to about −15° C. For example, the glass transition temperature of the optical adhesive layer PSA may be in a range of about −25° C. to about −20° C. For example, the glass transition temperature of the optical adhesive layer PSA may be about −19° C. In another embodiment, the glass transition temperature of the optical adhesive layer PSA may be about −20° C. In case that the glass transition temperature of the optical adhesive layer PSA satisfies the above-mentioned numerical range, the optical adhesive layer PSA may have excellent flexibility and the durability of the display device DD may be improved.

A creep value of the optical adhesive layer PSA at 60° C. may be in a range of about 10% to about 20%. For example, the creep value of the optical adhesive layer PSA at 60° C. may be about 15.8%. In case that the creep value of the optical adhesive layer PSA at 60° C. is less than the above-mentioned range, the optical adhesive layer PSA may be difficult to sufficiently deform during the folding operation of the display device DD, and in case that the creep value of the optical adhesive layer PSA at 60° C. is greater than the above-mentioned range, the resilience of the optical adhesive layer PSA may be insufficient.

As described above, the optical adhesive layer PSA may have a single-layered structure. For example, due to the single-layered structure of the optical adhesive layer PSA, an environment in which movement between layers of a material for implementing high refractive properties may be restricted may be provided, and the reliability of the light output efficiency of the display device DD may be secured. For example, in case that the optical adhesive layer PSA has a multi-layered structure and some layers adjacent to the passivation layer PVX of the multi-layered structure have a substantially large refractive index, a structure including a material such as a high refractive plasticizer may be prepared to implement a layer with the substantially large refractive index. However, in case that the high refractive plasticizer is selectively disposed in some layers, there may be a risk that the high refractive plasticizer penetrates other adjacent layers, which may reduce light output efficiency. However, according to the embodiment, the optical adhesive layer PSA may have a single-layered structure, so the aforementioned risk may be reduced.

Hereinafter, the disclosure will be described in more detail based on Examples and Comparative Examples. However, the following Examples and Comparative Examples are only examples for describing the disclosure in more detail, and the disclosure is not limited to the following Examples and Comparative Examples.

### 2. EXAMPLES AND COMPARATIVE EXAMPLES

### (1) Preparation—Example and Comparative Example

### Example

An optical adhesive material PSA according to an Example was prepared by mixing aliphatic methacrylate (A) as the first base resin, aromatic methacrylate (B) as the second base resin, xylene resin (C), sulfide-based aromatic organic materials (D) as organic additives; and ZrO2 (E) as inorganic particles in a weight ratio of 20:50:15:13:2 (A:B:C:D:E).

In order to secure the reliability of the experimental results more closely, optical adhesive materials PSA according to two types of Examples were manufactured using the same manufacturing method. Hereinafter, the manufactured (or prepared) optical adhesive materials PSA will be referred to as Example 1 and Example 2.

### Comparative Example

An optical adhesive material according to a Comparative Example was prepared by mixing an aromatic resin (A) as a base resin and a plasticizer (B) as an organic additive in a weight ratio of 70:30 (A:B).

In order to secure the reliability of the experimental results more closely, similar to the optical adhesive materials (PSA) according to Examples, optical adhesive materials according to two Comparative examples were manufactured using the same manufacturing method. Hereinafter, the manufactured (prepared) optical adhesive materials are referred to as Comparative Example 1 and Comparative Example 2, respectively.

### (2) Experimental Example—Rheological Property Measurement and Low Temperature Reliability Test

The rheological properties of the optical adhesive material PSA manufactured according to the Examples and the optical adhesive material manufactured according to the Comparative Examples were measured under a low temperature environment (−20° C.). The equipment used to measure the rheological properties of the target material in this experiment was TA Instrument's Rheometer (model name: DHR-3). The measured rheological properties are shown in the Table 1 below. The average values of the physical properties measured according to respective Examples and respective Comparative Examples are additionally included.

Using the same equipment, a low-temperature reliability test was conducted on the optical adhesive materials PSA manufactured according to the Examples and the optical adhesive materials manufactured according to the Comparative Examples under a low-temperature environment (−20° C.). The low-temperature reliability test measures the recovery rate after applying external force (for example, stress) to an object under a low-temperature environment.

TABLE 1

| | G′ | G″ | tanδ | Tg | Restoration | Reliability |
|---|---|---|---|---|---|---|
| Classification | [MPa] | [MPa] | (G″/G′) | (° C.) | rate (%) | determination |
| Example 1 | 1.66222 | 5.69598 | 3.42673 | −20.3 | 87 | O |
| Example 2 | 1.68247 | 5.17823 | 3.07775 | −20.5 | | |
| Example | 1.672345 | 5.437105 | 3.25224 | −20.39 | — | |
| average | | | | | | |
| Comparative | 1.25786 | 3.58079 | 2.84674 | −20.3 | 67 | X |
| Example 1 | | | | | | |
| Comparative | 1.16788 | 3.31971 | 2.84251 | −20.3 | | |
| Example 2 | | | | | | |
| Comparative | 1.21287 | 3.45025 | 2.844625 | −0.3 | — | |
| example | | | | | | |
| average | | | | | | |

Referring to Table 1, as the optical adhesive material PSA according to the embodiment includes materials, the optical adhesive material PSA may have rheological properties with a numerical range. The optical adhesive material PSA may have excellent foldable characteristics. Even in a low-temperature environment, a risk that the material properties of the optical adhesive material PSA is damaged may be reduced, and it can be seen that low-temperature reliability is excellent.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a display layer including a light emitting element including a first electrode, a second electrode, and a light emitting layer electrically connected to the first electrode and the second electrode; and
a sensor layer disposed on the display layer and including a conductive pattern layer, a passivation layer disposed on the conductive pattern layer and including an opening, and an optical adhesive layer disposed on the passivation layer, forming an interface with the passivation layer, and including an optical adhesive material, wherein
the passivation layer has a first refractive index,
the optical adhesive layer has a second refractive index greater than the first refractive index, and
the optical adhesive material includes an aliphatic monomer, an aromatic monomer, an organic additive, and an inorganic particle.

2. The display device of claim 1, wherein
the aliphatic monomer is represented by one of Chemical Formula 1 to Chemical Formula 6: 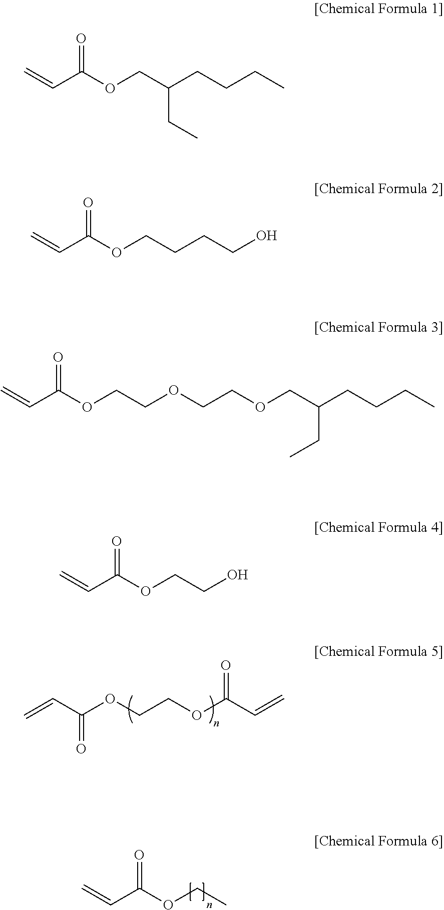
in Chemical Formula 5 and Chemical Formula 6, n is independently an integer from 1 to 20.

3. The display device of claim 2, wherein the aliphatic monomer constitutes in range of about 10 wt % to about 20 wt % of a total weight of the optical adhesive material.

4. The display device of claim 1, wherein
the aromatic monomer is represented by one of Chemical Formula 7 to Chemical Formula 12: 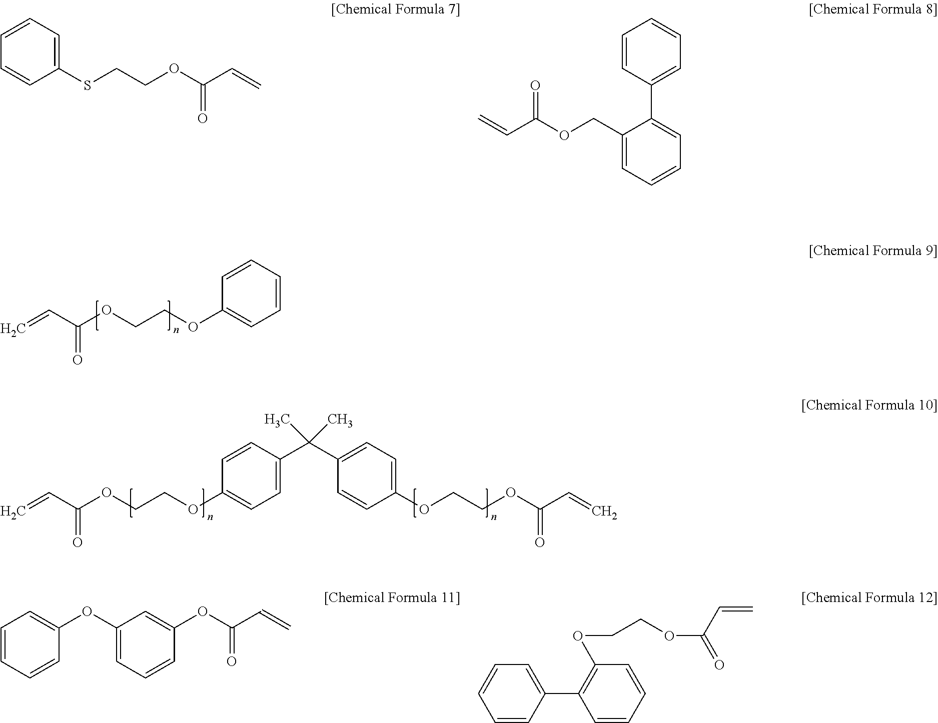
in Chemical Formula 9 and Chemical Formula 10, n is independently an integer from 0 to 6.

5. The display device of claim 4, wherein the aromatic monomer constitutes in a range of about 40 wt % to about 65 wt % of a total weight of the optical adhesive material.

6. The display device of claim 1, wherein
the organic additive includes a xylene resin, and
the xylene resin constitutes in a range of about 15 wt % to about 25 wt % of a total weight of the optical adhesive material.

7. The display device of claim 1, wherein
the organic additive includes a sulfide-based aromatic organic material, and
the sulfide-based aromatic organic material constitutes in a range of about 10 wt % to about 20 wt % of a total weight of the optical adhesive material.

8. The display device of claim 1, wherein a refractive index of the optical adhesive layer is in a range of about 1.56 to about 1.7.

9. The display device of claim 1, wherein a storage modulus of the optical adhesive material is in a range of about 0.01 MPa to about 1.8 MPa at −20° C.

10. The display device of claim 1, wherein a ratio of a loss modulus to a storage modulus of the optical adhesive material is in a range of about 3.0 to about 3.4.

11. The display device of claim 1, wherein a glass transition temperature of the optical adhesive material is in a range of about −25° C. to about −20° C.

12. The display device of claim 1, wherein the passivation layer includes at least one of an acrylic resin, an epoxy resin, a phenol resin, a polyamide resin, a polyimide resin, a methacryl-based resin, a polyisoprene, a vinyl-based resin, a urethane-based resin, a cellulose-based resin, a siloxane-based resin, and perylene-based resin.

13. The display device of claim 12, wherein the first refractive index of the passivation layer is in a range of about 1.45 to about 1.56.

14. The display device of claim 1, wherein the light emitting element is an organic light emitting element.

15. The display device of claim 1, wherein
the conductive pattern layer includes a first conductive pattern layer and a second conductive pattern layer,
the sensor layer further includes an insulating layer disposed between the first conductive pattern layer and the second conductive pattern layer, and
the passivation layer and the second conductive pattern layer are in contact with each other.

16. The display device of claim 1, wherein the optical adhesive layer has a single-layered structure.

17. The display device of claim 16, further comprising:
an upper layer disposed on the sensor layer directly adjacent to the optical adhesive layer.

18. The display device of claim 1, wherein the opening overlaps the light emitting layer in a plan view.

19. The display device of claim 1, wherein the display device is a flexible display device.

20. An optical adhesive material comprising:
an aliphatic monomer;
an aromatic monomer;
an organic additive including an organic material; and
an inorganic material.
